(19) United States
(12) Patent Application Publication
(10) Pub. No.: US 2012/0229749 A1
(43) Pub. Date: Sep. 13, 2012

(54) LIQUID CRYSTAL DISPLAY DEVICE AND METHOD FOR MANUFACTURING LIQUID CRYSTAL DISPLAY DEVICE

(75) Inventors: Jun Nishimura, Osaka (JP); Yoshihito Hara, Osaka (JP); Yukinobu Nakata, Osaka (JP)

(73) Assignee: SHARP KABUSHIKI KAISHA, Osaka (JP)

(21) Appl. No.: 13/510,740

(22) PCT Filed: Oct. 29, 2010
(86) PCT No.: PCT/JP2010/069307

§ 371 Date: May 18, 2012

(30) Foreign Application Priority Data
Nov. 20, 2009 (JP) 2009-265243

(51) Int. Cl. G02F 1/1333; H01L 33/08; G02F 1/1343

(52) U.S. Cl. 349/138; 349/139; 438/30; 257/E33.003

(57) ABSTRACT

Disclosed is a liquid crystal display device having a transparent substrate that has a main surface including a pixel arrangement region and a peripheral region, a switching element that is formed in the pixel arrangement region, an interlayer insulating film that is formed on the main surface of the transparent substrate, a wiring line that is formed such that an end is exposed from the interlayer insulating film, and a transparent conductive film that is formed so as to reach the wiring line from the main surface of the transparent substrate. An anisotropic conductive film is disposed on an upper surface of the transparent conductive film that is located on the main surface of the transparent substrate.

### TECHNICAL FIELD

The present invention relates to a liquid crystal display device and to a method of manufacturing the liquid crystal display device. Particularly, the present invention is an invention related to a liquid crystal display device that is provided with an active matrix substrate and an opposite substrate and that has a terminal formed on the active matrix substrate and to a method of manufacturing the liquid crystal display device.

### BACKGROUND ART

Conventionally, various types of liquid crystal display devices have been proposed. A liquid crystal display device typically includes an active matrix substrate, an opposite substrate that is disposed so as to face the active matrix substrate, and a liquid crystal layer disposed between the opposite substrate and the active matrix substrate.

On the active matrix substrate, a plurality of terminals, such as a gate pad, a source pad, and the like, are provided.

In liquid crystal display devices described in Japanese Patent Application Laid-Open Publication No. 2000-199917 and Japanese Patent Application Laid-Open Publication No. H9-197433, for example, a source terminal and a gate terminal that are exposed from a contact hole formed in an interlayer insulating film are formed.

### RELATED ART DOCUMENTS

### Patent Documents

Patent Document 1: Japanese Patent Application Laid-Open Publication No. 2000-199917

Patent Document 2: Japanese Patent Application Laid-Open Publication No. H9-197433

### SUMMARY OF THE INVENTION

### Problems to be Solved by the Invention

In a conventional liquid crystal display device, when forming a contact hole in an interlayer insulating film, forming an ITO (Indium Tin Oxide) film at a prescribed location in the formed contact hole, and the like, the interlayer insulating film and the ITO film are patterned by photolithography.

When performing photolithography, it is typical to secure a certain level of margin in the event that a shift in position occurs.

On the other hand, in recent years, the width of a terminal itself and the interval between the terminals have become narrower, and it is becoming difficult to secure a margin when performing photolithography.

Because of this, in a conventional liquid crystal display device and a method of manufacturing the liquid crystal display device, it is becoming difficult to further reduce the size of terminals.

The present invention seeks to address the problems described above, and its object is to provide a liquid crystal display device in which the size of terminals is reduced and a method of manufacturing the liquid crystal display device.

### Means for Solving the Problems

A liquid crystal display device according to the present invention has a substrate having a main surface that includes a pixel arrangement region and a peripheral region formed in a periphery of the pixel arrangement region, a switching element formed in the pixel arrangement region, a wiring line that is connected to the switching element and that is formed such that an end thereof reaches the peripheral region, a transparent conductive film formed on the main surface of the substrate located in the peripheral region and extending so as to reach the end of the wiring line located in the peripheral region, an external terminal disposed above the transparent conductive film, and a connecting member that is disposed between a portion of the transparent conductive film formed on the main surface of the substrate and the external terminal and that electrically connects the transparent conductive film to the external terminal.

Preferably, an insulating film that is formed so as to cover a region of the main surface of the substrate in which the switching element is located is further provided. The end of the wiring line located in the peripheral region is formed so as to be exposed from the insulating film. The transparent conductive film and the main surface of the substrate located in the periphery of the transparent conductive film are formed so as to be exposed from the insulating film.

Preferably, a width of the transparent conductive film is formed so as to be wider than a width of the wiring line.

Preferably, the transparent conductive film is formed so as to cover an upper surface and a side surface of the wiring line.

Preferably, the transparent conductive film is formed so as to cover a portion of the wiring line that is exposed from the insulating film and to reach over the insulating film. Preferably, the end of the wiring line is located on a side of the pixel arrangement region compared to a connected portion between the transparent conductive film and the connecting member.

A method of manufacturing a liquid crystal display device according to the present invention includes the following steps: preparing a substrate having a main surface that includes a first region that becomes a pixel arrangement region and a second region that becomes a peripheral region located in a periphery of the pixel arrangement region; forming a switching element in the first region; forming a wiring line formed so as to be connected to the switching element and to reach the second region; forming a transparent conductive film on the main surface of the substrate located in the second region so as to reach the end of the wiring line; disposing a connecting member on a portion of the transparent conductive film that is located on the main surface of the substrate; and disposing an external terminal on an upper surface of the connecting member to electrically connect the external terminal to the transparent conductive film.

Preferably, forming the switching element includes forming a gate electrode in the first region, forming a gate insulating film on the gate electrode, forming a semiconductor layer on the gate insulating film, and forming a source electrode and a drain electrode on the semiconductor layer. The wiring line is connected to either the gate electrode or the source electrode, and the end thereof is formed so as to reach the second region. Forming the insulating film on the source electrode and the drain electrode and exposing the end of the wiring line from the insulating film are further included. The transparent conductive film is formed so as to be connected to the end of the wiring line that is exposed from the insulating film.

Preferably, a width of the transparent conductive film is formed so as to be wider than a width of the end of the wiring line. Preferably, the transparent conductive film is formed so as to cover an upper surface and side faces of the end of the wiring line exposed from the insulating film. Preferably, the transparent conductive film is formed so as to reach over the insulating film.

### Effects of the Invention

According to a liquid crystal display device and a method of manufacturing the liquid crystal device according to the present invention, the size of terminals can be reduced.

### BRIEF DESCRIPTION OF THE DRAWINGS

FIG. 1 is an exploded perspective view showing a configuration of a television receiver 500 according to Embodiment 1 of the present invention.

FIG. 2 is a perspective view schematically showing a liquid crystal display device 300.

FIG. 3 is a plan view schematically showing a liquid crystal display element 200.

FIG. 4 is an exploded perspective view showing an arrangement state of a liquid crystal display panel 101 and a polarizing plate 156.

FIG. 5 is a plan view of the liquid crystal display panel 101.

FIG. 6 is a circuit diagram showing a thin film transistor array formed on an active matrix substrate 130.

FIG. 7 is a cross-sectional view of the liquid crystal display panel 101 in a display region 103.

FIG. 8 is a cross-sectional view of the active matrix substrate 130 showing a thin film transistor 115 in detail.

FIG. 9 is a plan view of gate pads 112 formed in a peripheral circuit region.

FIG. 10 is a cross-sectional view of a cross-section along the line X-X in FIG. 9 in a state in which an anisotropic conductive film 160 and a gate driver 152 are disposed on an upper surface of the transparent conductive film 118A.

FIG. 11 is a cross-sectional view along the line XI-XI in FIG. 9.

FIG. 12 is a cross-sectional view along the line XII-XII in FIG. 9.

FIG. 13 is a cross-sectional view along the line XIII-XIII in FIG. 9.

FIG. 14 is a cross-sectional view of a region that becomes the display region 103.

FIG. 15 is a cross-sectional view in a region that becomes a peripheral region 105 during a process step shown in FIG. 14.

FIG. 16 is a cross-sectional view showing a process step after process steps shown in FIGS. 14 and 15.

FIG. 17 is a cross-sectional view in a region that becomes the peripheral region 105 during a process step shown in FIG. 16.

FIG. 18 is a cross-sectional view in a region that becomes the display region 103 showing a process step after process steps shown in FIGS. 16 and 17.

FIG. 19 is a cross-sectional view in a region that becomes the peripheral region 105 during a process step shown in FIG. 18.

FIG. 20 is a cross-sectional view of the display region 103 showing a process step after process steps shown in FIGS. 18 and 19.

FIG. 21 is a cross-sectional view of the peripheral region 105 during a process step shown in FIG. 20.

FIG. 22 is a cross-sectional view of the display region 103 in a liquid crystal display device according to Embodiment 2.

FIG. 23 is a plan view of source pads 114 formed in the peripheral region 105.

FIG. 24 is a cross-sectional view along the line XXIV-XXIV shown in FIG. 23.

FIG. 25 is a cross-sectional view along the line XXV-XXV shown in FIG. 23.

FIG. 26 is a cross-sectional view along the line XXVI-XXVI in FIG. 24.

FIG. 27 is a cross-sectional view along the line XXVII-XXVII in FIG. 24.

FIG. 28 is a cross-sectional view of the peripheral region 105 in which the source pad 114 of a liquid crystal display device according to Embodiment 3 is formed.

FIG. 29 is a cross-sectional view showing a modification example of the source pad 114 shown in FIG. 28.

FIG. 30 is a cross-sectional view of a liquid crystal display device according to Embodiment 4.

FIG. 31 is a cross-sectional view of a gate pad 112.

FIG. 32 is a plan view of a liquid crystal display device in which COG (Chip On Glass) is used.

FIG. 33 is a cross-sectional view along the line XXXIII-XXXIII shown in FIG. 32.

### DETAILED DESCRIPTION OF EMBODIMENTS

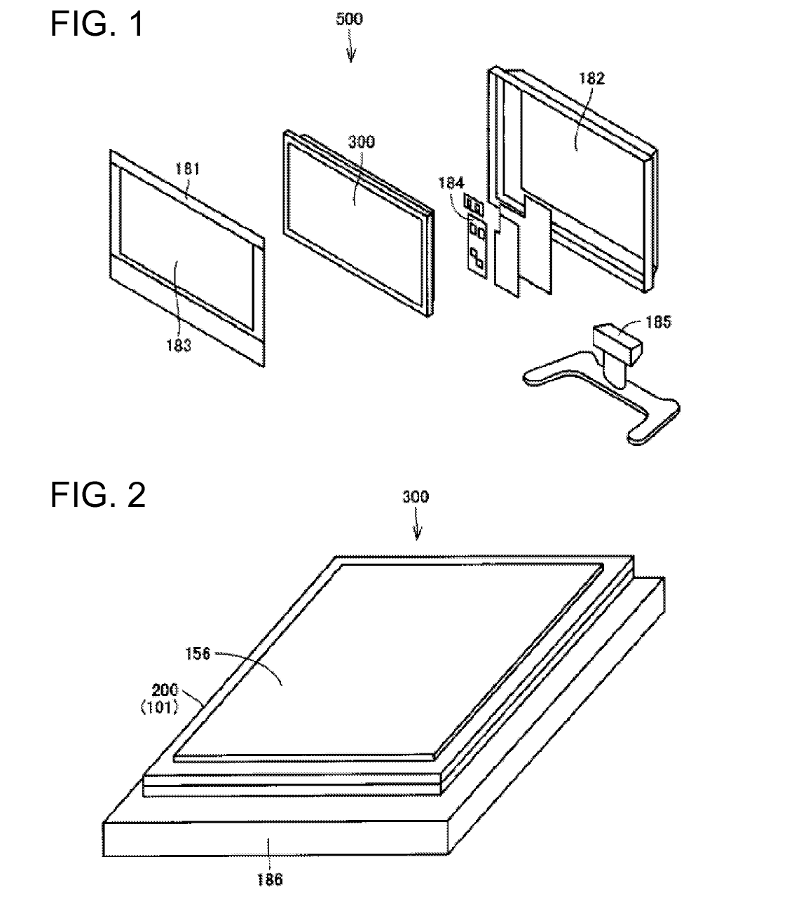

Liquid crystal display devices according to the present invention and a method of manufacturing the liquid crystal display devices are described using FIGS. 1 to 27.

### Embodiment 1

FIG. 1 is an exploded perspective view showing a configuration of a television receiver 500 according to Embodiment 1 of the present invention. As shown in FIG. 1, the television receiver 500 has a case 181 disposed on a front surface side, a case 182 disposed on a back surface side, a liquid crystal display device 300 disposed between the case 181 and the case 182, an operation circuit 184, and a support member 185.

The liquid crystal display device 300 is surrounded by the case 181 and the case 182, and is held between the case 181 and the case 182.

An opening 183 is formed in the case 181, and an image displayed on the liquid crystal display device 300 can be transmitted to the outside. The case 182 has the operation circuit 184 for operating the liquid crystal display device 300. The case 182 is supported by the support member 185.

FIG. 2 is a perspective view schematically showing the liquid crystal display device 300. As shown in FIG. 2, the liquid crystal display device 300 has a liquid crystal display element 200 that includes a liquid crystal display panel 101, a polarizing plate 156 attached to one of the main surfaces of the liquid crystal display panel 101, a polarizing plate attached to the other one of the main surfaces of the liquid crystal display panel 101, and a backlight unit 186 that irradiates the liquid crystal display panel 101 with light.

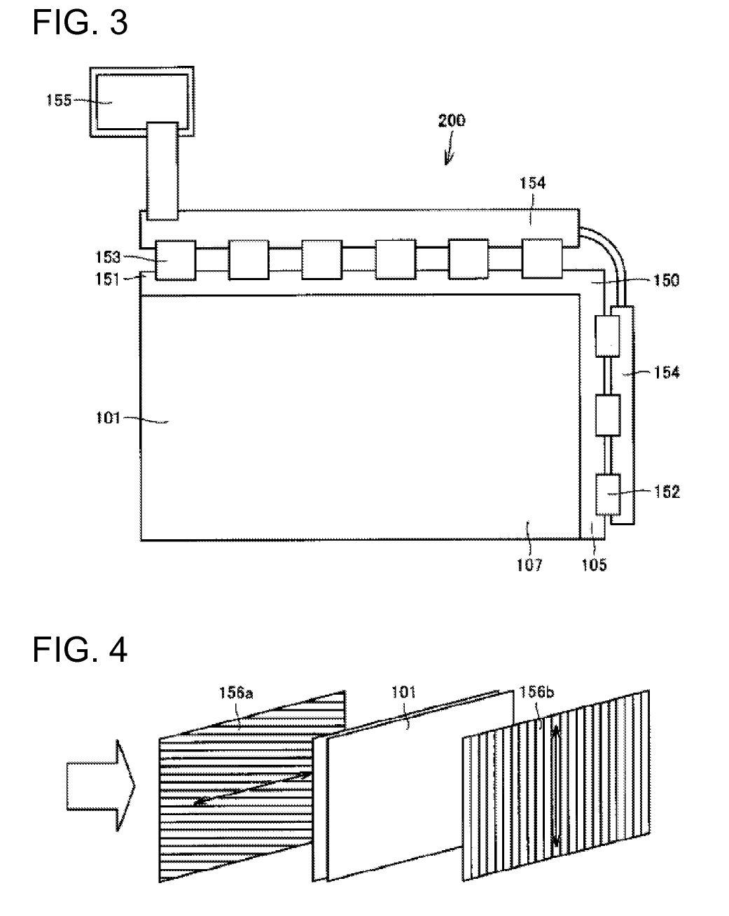

FIG. 3 is a plan view schematically showing the liquid crystal display element 200. As shown in FIG. 3, the liquid crystal display element 200 has the liquid crystal display panel 101, gate drivers 152 connected to a gate terminal 150 of the liquid crystal display panel 101, source drivers 153 connected to a source terminal 151 of the liquid crystal display panel 101, a printed substrate wiring line 154 to which the gate drivers 152 and the source drivers 153 are connected, and a display control circuit 155 to which the printed substrate wiring line 154 is connected.

FIG. 4 is an exploded perspective view showing an arrangement state of the liquid crystal display panel 101 and the polarizing plates 156. As shown in FIG. 4, on one of the main surfaces of the liquid crystal display panel 101, a polarizing plate 156a is attached. On the other one of the main surfaces of the liquid crystal display panel 101, another polarizing plate 156b is attached.

Here, a polarizing axis direction of the polarizing plate 156a and a polarizing axis direction of the polarizing plate 156b are formed so as to be orthogonal to each other. Light from the backlight unit 186 shown in FIG. 2 is emitted to the polarizing plate 156a.

The liquid crystal display panel 101 includes an active matrix substrate, an opposite substrate that is disposed so as to face the active matrix substrate with an space therebetween, and a liquid crystal layer that is encapsulated between the active matrix substrate and the opposite substrate. Further, the polarizing plate 156a is disposed on the opposite side from the liquid crystal layer with respect to the active matrix substrate, and the polarizing plate 156b is disposed on the opposite side from the liquid crystal layer with respect to the opposite substrate.

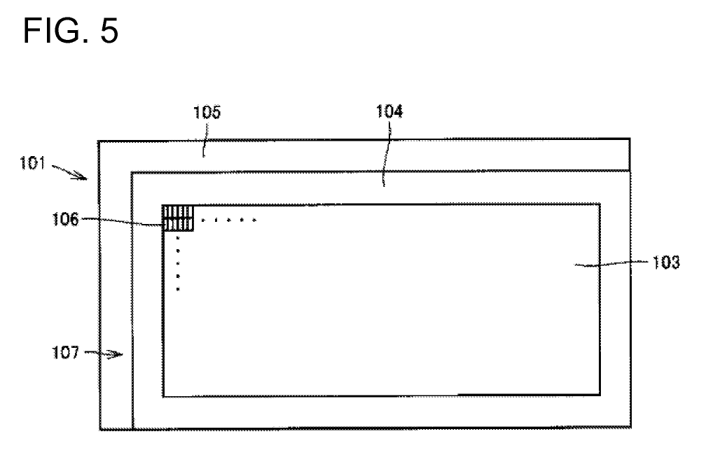

FIG. 5 is a plan view of the liquid crystal display panel 101. As shown in FIG. 5, the liquid crystal display panel 101 has a pixel arrangement region 107 that includes a display region 103 and a non-display region 104 and a peripheral region 105 that is located in a periphery of the pixel arrangement region 107.

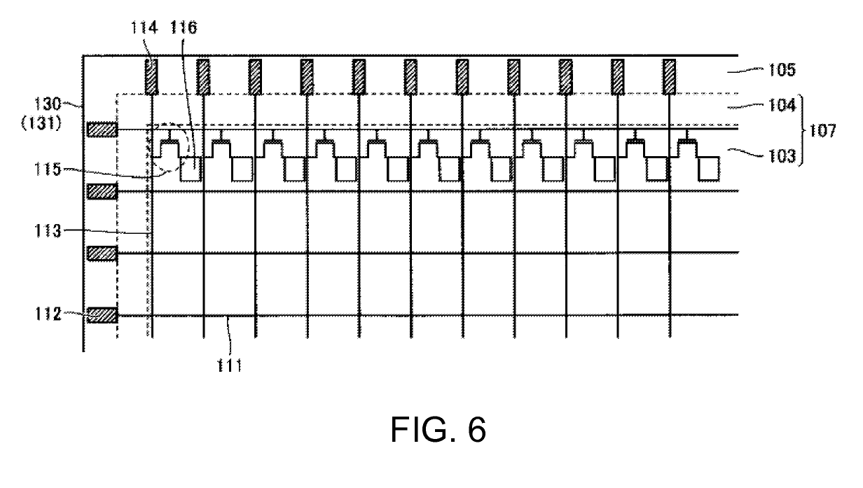

The display region 103 is a region that displays an image, and is formed of a plurality of pixels. The non-display region 104 is a region that does not display any image, and is disposed in the periphery of the display region 103. FIG. 6 is a circuit diagram showing a thin film transistor array formed on the active matrix substrate 130.

The active matrix substrate 130 has a transparent substrate 131 that includes the pixel arrangement region 107 and the peripheral region 105 located in the periphery of the pixel arrangement region 107.

Of a main surface of the transparent substrate 131, in a portion where the display region 103 of the pixel arrangement region 107 is located, a plurality of thin film transistors (switching elements) 115 are arranged. A plurality of gate lines (wiring lines) 111 connected to gate electrodes of the thin film transistors 115 and a plurality of data lines (wiring lines) 113 connected to source electrodes of the thin film transistors 115 are formed on the active matrix substrate 130. Pixel electrodes 116 are connected to drain electrodes of the thin film transistors 115.

The active matrix substrate 130 is typically in a rectangular shape. The gate lines 111 extend in a lengthwise direction of the active matrix substrate 130. The plurality of gate lines 111 are arranged with intervals therebetween in a widthwise direction of the active matrix substrate 130. The data lines 113 extend in the widthwise direction, and the plurality of data lines 113 are arranged with intervals therebetween in the lengthwise direction.

A single pixel electrode 116 is disposed in a region surrounded by the gate lines 111 and the data lines 113.

The gate lines 111 are led out from the thin film transistors 115, and extend so as to reach the peripheral region 105 from the pixel arrangement region 107. Further, gate pads 112 are formed at portions of the gate lines 111 that are located on the peripheral region 105.

The data lines 113 are led out from the thin film transistors 115, and extend so as to reach the peripheral region 105 from the pixel arrangement region 107. Source pads 114 are formed at portions of the data lines 113 that are located on the peripheral region 105.

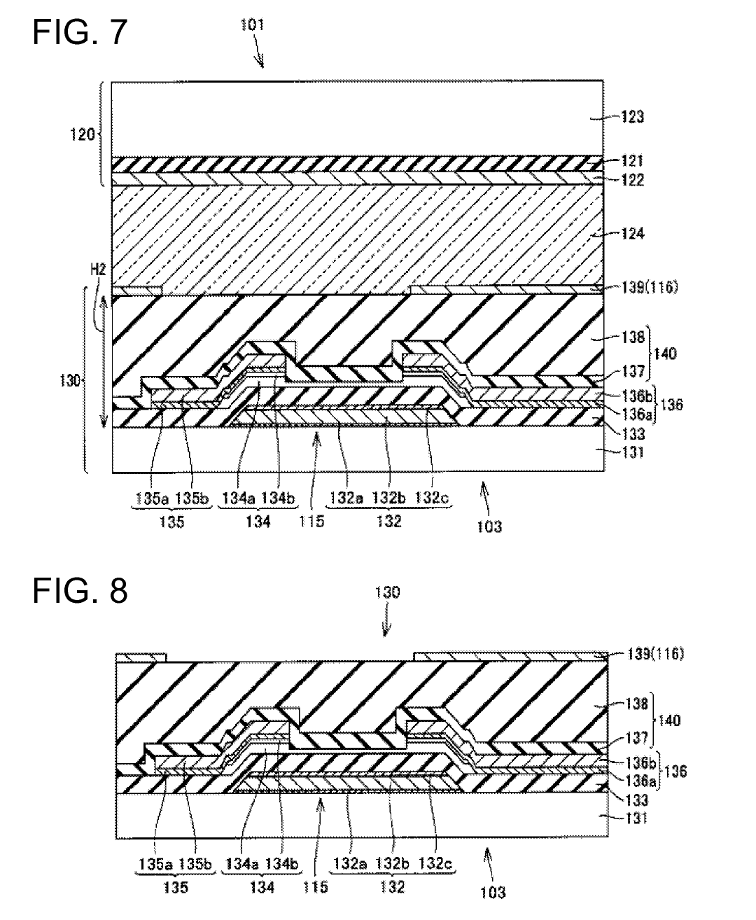

FIG. 7 is a cross-sectional view of the liquid crystal display panel 101 in the display region 103. As shown in FIG. 7, an opposite substrate 120 has a transparent substrate 123 such as a glass substrate or the like, a color filter 121 formed on a main surface that faces the active matrix substrate 130 of the main surfaces of the transparent substrate 123, and an opposite electrode 122 disposed closer to the side of the active matrix substrate 130 than the color filter 121.

The opposite electrode 122 and the pixel electrode 116 are disposed so as to face each other through a liquid crystal layer 124. The active matrix substrate 130 has the transparent substrate 131 such as a glass substrate or the like and the thin film transistor 115 formed on the transparent substrate 131.

FIG. 8 is a cross-sectional view of the active matrix substrate 130 showing the thin film transistor 115 in detail. The thin film transistor 115 has a gate electrode 132 formed on a main surface that faces the opposite substrate 120 among surfaces of the transparent substrate 131, a gate insulating film 133 formed on the main surface of the transparent substrate 131 so as to cover the gate electrode 132, a semiconductor layer 134 that is located on the gate insulating film 133 and that is located above the gate electrode 132, and a source electrode 135 and a drain electrode 136 that are formed on upper surfaces of the semiconductor layer 134 and the gate insulating film 133 so as to cover a portion of the semiconductor layer 134 and that are formed with a gap therebetween.

Further, an interlayer insulating film 140 (a passivation film and a planarization film) is formed so as to cover the thin film transistor 115. An ITO film 139 (pixel electrode 116) is formed on the interlayer insulating film 140. This pixel electrode 116 is electrically connected to the drain electrode 136. Specifically, a contact hole that is not shown in the figure is formed in the interlayer insulating film 140. The pixel electrode 116 extends along an inner circumferential surface of the contact hole, and the pixel electrode 116 and the drain electrode 136 are connected to each other.

The gate electrode 132 includes a metal film 132a formed on the main surface of the transparent substrate 131, a metal film 132b formed on the metal film 132a, and a metal film 132c formed on the metal film 132b. The metal film 132a and the metal film 132c are formed of a metal material such as titanium (Ti) or the like, for example. The metal film 132b is formed of a metal material such as aluminum (Al) or the like. Here, the respective metal films are not limited to the examples described above.

The metal film 132a may be formed of molybdenum nitride (MoN), and the metal film 132b may be formed of aluminum (Al), for example. Further, the metal film 132c may be formed of molybdenum (Mo).

The gate insulating film 133 is formed of silicon nitride (SiNx: x is a positive number) or the like, for example.

The semiconductor layer 134 includes an amorphous silicon film (a-Si film: i layer) 134a that becomes a channel portion of the thin film transistor 115 and an amorphous silicon film (n+layer) 134b that is formed on the amorphous silicon film 134a and that brings the source and drain electrodes into contact with each other.

The source electrode 135 includes a metal film 135a formed of titanium or the like and a metal film 135b that is located on the metal film 135a and that is formed of aluminum or the like. The drain electrode 136 also includes a metal film 136a formed of titanium or the like and a metal film 136b that is formed on the metal film 136a and that is formed of aluminum or the like.

The interlayer insulating film 140 includes a passivation film 137 and a planarization film 138 that is formed on the passivation film 137. The passivation film 137 is formed of a silicon nitride film, and is formed by a CVD (Chemical Vapor Deposition) method at approximately 250 degrees, for example. Here, both the passivation film 137 and the gate insulating film 133 are formed of silicon nitride films. However, the gate insulating film 133 has a denser composition than the passivation film 137.

The planarization film 138 is formed of an organic material such as an acrylic-based synthetic resin or the like. Thus, the planarization film 138 is an organic insulating film, and the passivation film 137 formed under the planarization film 138 is an inorganic insulating film.

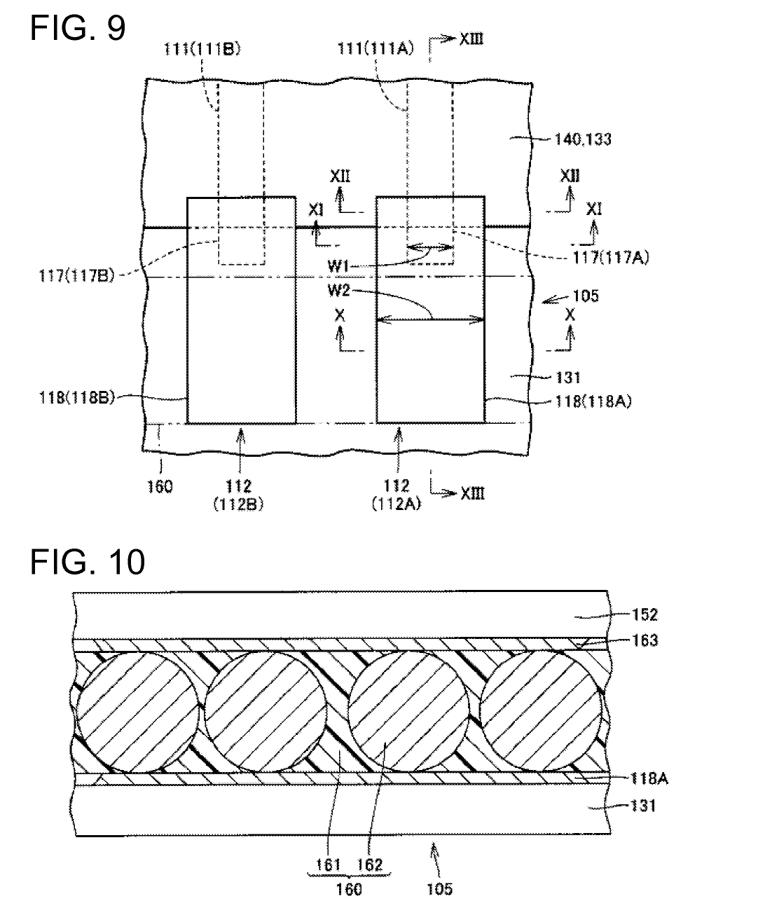

FIG. 9 is a plan view of gate pads 112 formed in a peripheral circuit region. As shown in FIG. 9, a portion of the main surface of the transparent substrate 131 in which the peripheral region 105 is located is exposed from insulating films, such as the interlayer insulating film 140, the gate insulating film 133, and the like. Here, the portion of the main surface of the transparent substrate 131 where the peripheral region 105 is located is exposed not only from the insulating films, but also from the semiconductor layer and the metal films constituting the source electrode and the drain electrode.

Further, an end 117A of a gate line 111A and an end 117B of a gate line 111B are formed so as to reach the peripheral region 105 and to be exposed from the interlayer insulating film 140 and the gate insulating film 133.

Transparent conductive films 118A and 118B are connected to the ends 117A and 117B of the gate lines 111A and 111B, respectively. The transparent conductive films 118A and 118B are formed of an ITO film, an IZO (Indium Zinc Oxide) film, or the like, for example.

The transparent conductive films 118A and 118B are formed so as to cover side surfaces and upper surfaces of the ends 117A and 117B from the main surface of the transparent substrate 131 that is exposed from the interlayer insulating film 140 and the gate insulating film 133. This way, electrical connection between the transparent conductive films 118A and 118B and the ends 117A and 117B can be secured. Gate pads 112A and 112B are formed by the transparent conductive films 118A and 118B.

FIG. 10 is a cross-section along the line X-X in FIG. 9, and is a cross-sectional view of a state in which an anisotropic conductive film 160 and the gate driver 152 are disposed on the upper surface of the transparent conductive film 118A.

As shown in FIGS. 10 and 9, a portion of the transparent conductive film 118A that is located on the peripheral region 105 has a planar surface, and functions as a terminal.

Further, on an upper surface of the portion of the transparent conductive film 118A that is located on the main surface of the peripheral region 105, the anisotropic conductive film 160 is disposed. The gate driver 152 is disposed on an upper surface of the anisotropic conductive film 160.

The anisotropic conductive film (connecting member) 160 includes an insulating binder 161 and a plurality of conductive particles 162, which are conductive, disposed inside the binder 161. On a lower surface side of the gate driver 152, a connecting terminal (external terminal) 163 is disposed. Further, electrical connection between the transparent conductive film 118A and the connecting terminal 163 is secured by the conductive particles 162 of the anisotropic conductive film 160 disposed between the transparent conductive film 118A and the connecting terminal 163 of the gate driver 152.

The conductive particles 162 are constituted of metal particles, and connect the transparent conductive film 118A and the connecting terminal 163 to each other. This way, the transparent conductive films 118 and the anisotropic conductive film 160 become electrically connected to each other at a contact portion (connected portion) between the transparent conductive films 118 and the anisotropic conductive film 160. Electrical connection between the anisotropic conductive film 160 and the connecting terminal 163 is secured at a contact portion (connected portion) between the anisotropic conductive film 160 and the connecting terminal 163. Here, it is sufficient if the transparent conductive film 118A and the gate line 111A are connected to each other. Even if the position of the end of the gate line 111A is shifted, it is possible to secure electrical connection between the transparent conductive film 118A and the connecting terminal 163. Because of this, the yield of the liquid crystal display device can be improved. As shown in FIG. 9 above, the main surface of the transparent substrate 131 located between the gate pads 112A and 112B, which are adjacent to each other, is exposed from the interlayer insulating film 140 and the gate insulating film 133.

Because of this, particle diameters of the conductive particles 162 can be made small by bringing the connecting terminal 163 and the transparent conductive films 118A and 118B closer to each other. By using the conductive particles 162 having small diameters, the plurality of conductive particles 162 are aligned on the transparent conductive film 118A, and large contact areas can be secured between the conductive particles 162 and the transparent conductive film 118A, as well as between the conductive particles 162 and the connecting terminal 163.

Further, by using the conductive particles 162 having small diameters, it is possible to prevent a single conductive particle 162 from being disposed and bridging across the gate pad 112A and the gate pad 112B, thereby making it possible to prevent an occurrence of a short circuit between the gate pad 112A and the gate pad 112B. Because of this, even when the gate pad 112A and the gate pad 112B are in a close proximity of each other, it is possible to prevent an occurrence of a short circuit between the gate pad 112A and the gate pad 112B. Further, it is possible to shorten the interval between the gate pad 112A and the gate pad 112B.

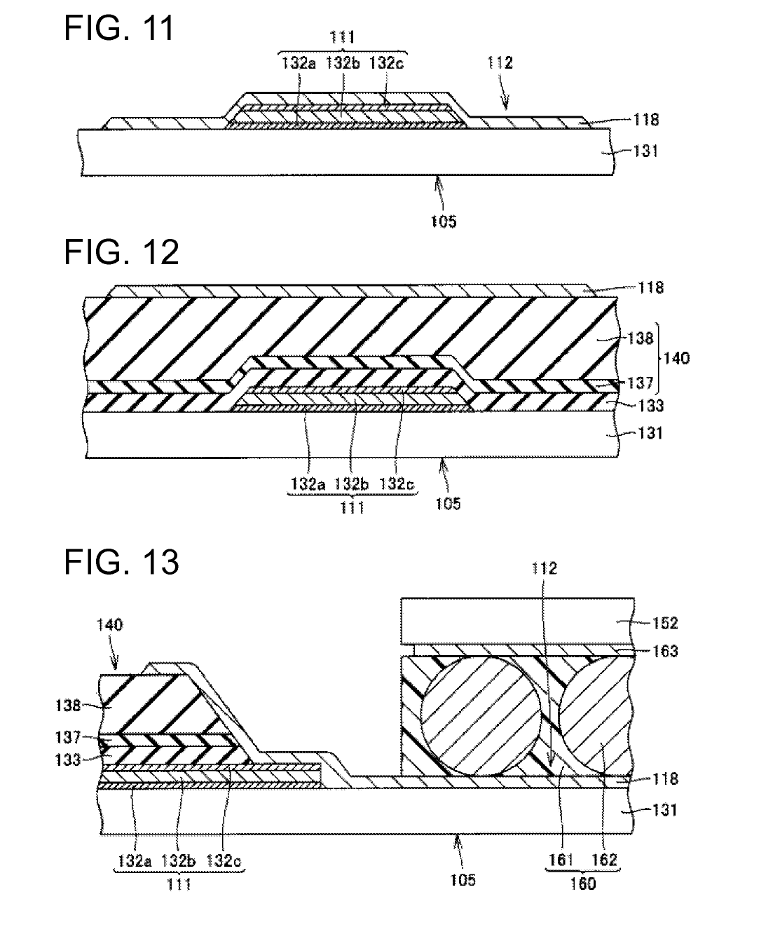

FIG. 11 is a cross-sectional view along the line XI-XI in FIG. 9 above. As shown in FIG. 11, the transparent conductive film 118 is formed to spread on the side faces and the upper surface of the end of the gate line 111. Because of this, electrical connection between the gate line 111 and the transparent conductive film 118 can be secured.

FIG. 12 is a cross-sectional view along the line XII-XII in FIG. 9. FIG. 13 is a cross-sectional view along the line XIII-XIII in FIG. 9. As shown in FIGS. 12 and 13, at a portion of the main surface of the transparent substrate 131 that is located closer to the display region 103 side than the peripheral region 105, the gate insulating film 133 and the interlayer insulating film 140 are formed on the upper surface of the gate line 111. Here, the interlayer insulating film 140 includes the passivation film 137 that is formed on the gate insulating film 133 and the planarization film 138 that is formed on the passivation film 137.

As shown in FIG. 13, the transparent conductive film 118 is formed so as to reach the upper surface of the interlayer insulating film 140 from the main surface of the transparent substrate 131 located in the peripheral region 105 through the top surface of the end of the gate line 111. As shown in FIGS. 13 and 9 above, the end of the gate line 111 is located closer to the pixel arrangement region 107 side than the connection portion between the transparent conductive film 118 and the anisotropic conductive film 160. As described, the gate line 111 is away from the contact between the anisotropic conductive film 160 and the transparent conductive film 118. As a result, the anisotropic conductive film 160 is disposed in a planar manner in the connected portion between the anisotropic conductive film 160 and the transparent conductive film 118 and in the proximity thereof. By planarizing the portion of the anisotropic conductive film 160 connected to the transparent conductive film 118 this way, the transparent conductive film 118 and the anisotropic conductive film 160 can be connected to each other reliably.

A method of manufacturing a liquid crystal display device that is configured as described above is described.

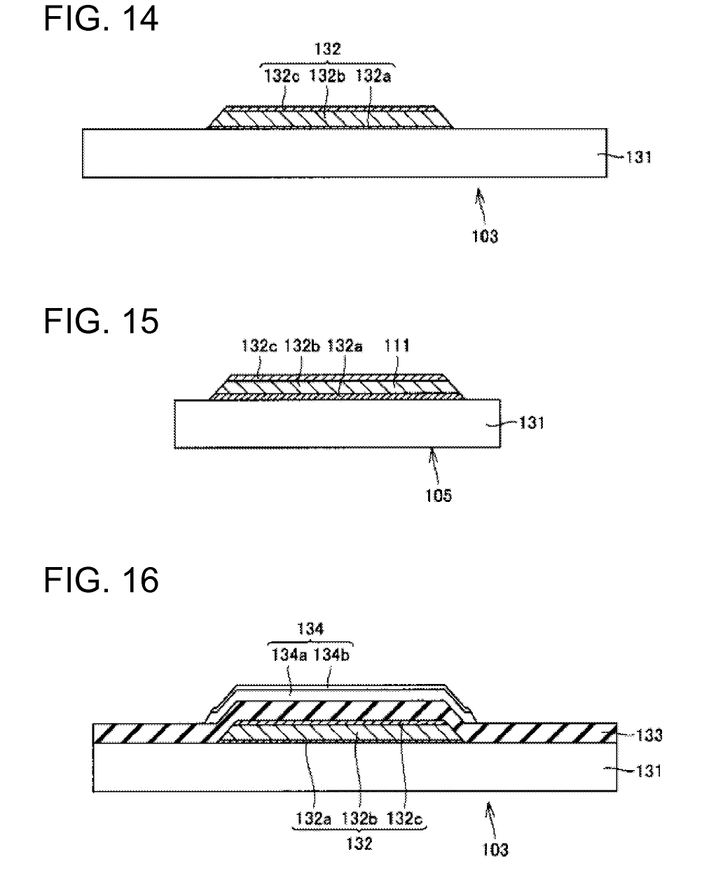

FIG. 14 is a cross-sectional view in a region that becomes the display region 103, and is a cross-sectional view in which the gate electrode 132 is formed on the main surface of the transparent substrate 131. FIG. 15 is a cross-sectional view in a region that becomes the peripheral region 105 in a process step shown in FIG. 14 above.

As shown in FIGS. 14 and 15, first, the transparent substrate 131 having a main surface is prepared. Here, the main surface of the transparent substrate 131 has a region that becomes the display region 103 and a region that becomes the peripheral region 105. Then, of the main surface of the transparent substrate 131, on the region that becomes the peripheral region 105 and the region that becomes the display region 103, the metal film 132a, the metal film 132b, and the metal film 132c are formed. Then, these laminated metal films are patterned to form the gate electrode 132 and the gate line 111. The gate electrode 132 and the gate line 111 are formed at the same time by patterning the laminated metal films.

FIG. 16 is a cross-sectional view showing a process step after the process steps shown in FIGS. 14 and 15, and is a cross-sectional view in the region that becomes the display region 103. FIG. 17 is a cross-sectional view in the region that becomes the peripheral region 105 during the process step shown in FIG. 16.

As shown in FIGS. 16 and 17, the amorphous silicon film (i layer) 134a and the amorphous silicon film (n+layer) 134b that is formed on the amorphous silicon film 134a are laminated in this order. Then, the amorphous silicon film (i layer) 134a and the amorphous silicon film (n+layer) 134b, which are laminated, are patterned to form the semiconductor layer 134. The semiconductor layer 134 is formed on an upper surface of the gate insulating film 133 that is located above the gate electrode 132.

Here, in the region that becomes the peripheral region 105, the amorphous silicon film (i layer) 134a and the amorphous silicon film (n+layer) 134b are removed during the patterning described above.

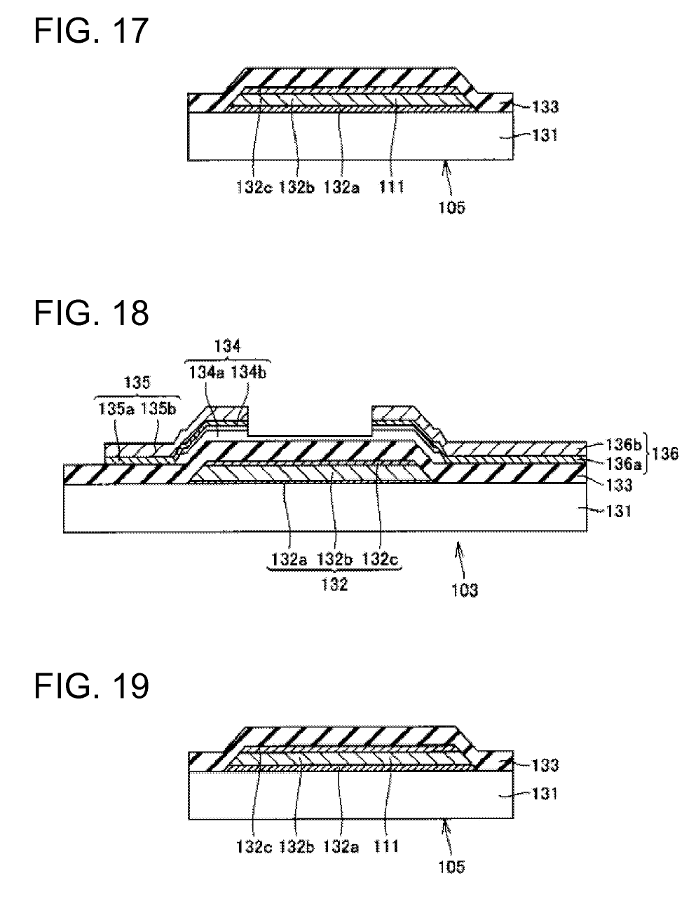

FIG. 18 is a cross-sectional view in a region that becomes the display region 103 showing a process step after the process steps shown in FIGS. 16 and 17 above. FIG. 19 is a cross-sectional view in the region that becomes the peripheral region 105 during the process step shown in FIG. 18 above.

A metal film formed of titanium or the like and a metal film formed of aluminum or the like are formed in this order so as to cover the semiconductor layer 134.

Then, the laminated metal films are patterned. This way, the source electrode 135 and the drain electrode 136 are formed. Here, when the source electrode 135 and the drain electrode 136 are formed, the data line 113 is formed at the same time. The thin film transistor 115 and the display region 103 are formed this way. Further, the peripheral region 105 is defined in the periphery of the display region 103.

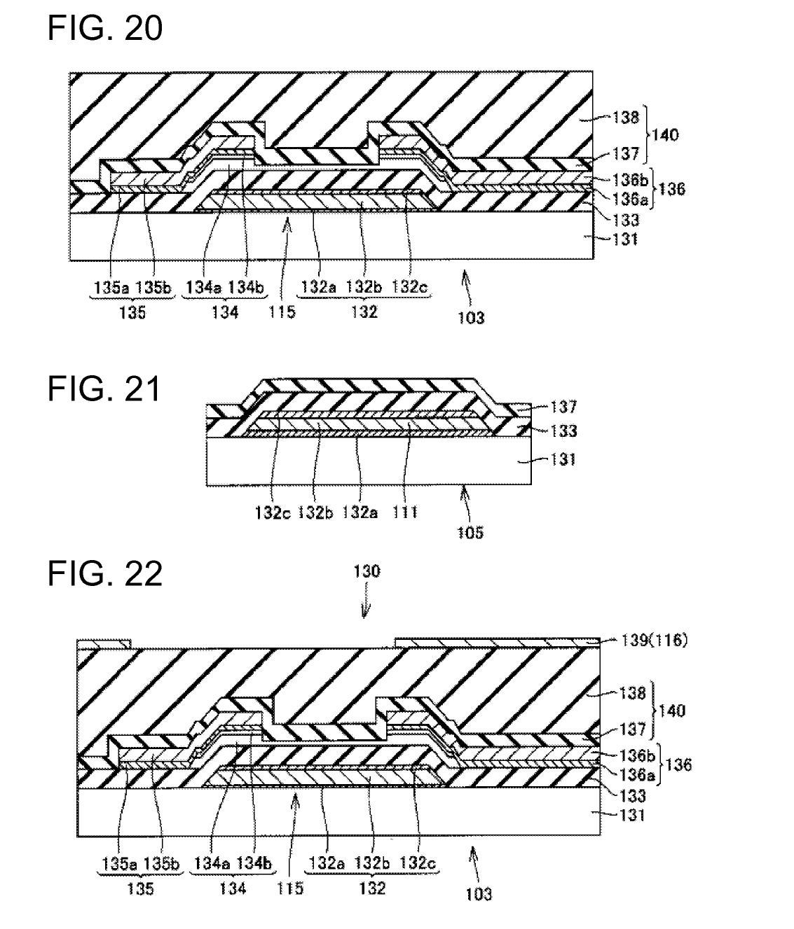

FIG. 20 is a cross-sectional view of the display region 103 showing a process step after the process steps shown in FIGS. 18 and 19. FIG. 21 is a cross-sectional view of the peripheral region 105 during the process step shown in FIG. 20. As shown in FIGS. 20 and 21, the passivation film 137 and the planarization film 138 are formed so as to cover the source electrode 135, the drain electrode 136, the data line 113, and the like.

The planarization film 138 is formed of an organic material such as an acrylic-based synthetic resin or the like. This planarization film 138 is patterned to remove a portion of the planarization film 138 that is located in the peripheral region 105. Here, when the patterning is performed, a contact hole extending towards the drain electrode 136 and the like are also formed in the planarization film 138, for example.

Using this patterned planarization film 138 as a mask, the passivation film 137 and the gate insulating film 133 are patterned. This way, the passivation film 137 and the gate insulating film 133, which are formed on the peripheral region 105, are removed, and the main surface of the transparent substrate 131 is exposed to the outside. On the other hand, in the peripheral region 105, a contact hole that runs through the planarization film 138 and the passivation film 137 to reach the drain electrode 136 is formed.

Then, as shown in FIG. 8, the ITO film 139 is formed, and the ITO film 139 is patterned. This way, the pixel electrode 116 is formed on the upper surface of the planarization film 138. The pixel electrode 116 is also formed in the contact hole that runs through the planarization film 138 and the passivation film 137, and is electrically connected to the drain electrode 136.

On the other hand, in the peripheral region 105, the transparent conductive films 118A and 118B are formed as shown in FIG. 9.

Here, the width W2 of the transparent conductive film 118 is formed wider than the width W1 of the gate line 111. Because of this, even if the position of the mask is shifted or like anomaly occurs when patterning the ITO film 139 to form the transparent conductive film 118, connection between the transparent conductive film 118 and the gate line 111 can be secured. As a result, the yield of manufactured liquid crystal display devices can be improved.

Further, when patterning the ITO film 139, a portion of the main surface of the transparent substrate 131 that is located in the peripheral region 105 is exposed from the interlayer insulating film 140 and the gate insulating film 133. As a result, when patterning the ITO film 139 to form the transparent conductive film 118, it is sufficient if the relative positions of the transparent conductive film 118 and the gate line 111 are determined, and there is no need to take into account arrangement of their positions with respect to other members. As a result, the number of objects that need to be positioned accurately is small. Because of this, the yield of the liquid crystal display devices can be improved.

When forming the transparent conductive film 118, it is sufficient if its relative position with respect to the gate line 111 is determined accurately. Therefore, a margin in photolithography can be made small.

As described, the margin in photolithography can be made small. As a result, an interval between the transparent conductive films 118 themselves can be made smaller, and the width W2 itself of the transparent conductive film 118 can be made smaller. Because of this, the size of the gate pads 112 can be reduced. Further, shapes of the transparent conductive films 118 themselves are not limited. Therefore, the shapes are not limited to rectangular shapes shown in FIG. 9, and other polygonal shapes, circular shapes, elliptical shapes, and the like can be used.

The transparent conductive films 118 are formed so as to cover ends of the gate lines 111 that are exposed from the interlayer insulating film 140 and the data line 113. Because of this, it is possible to prevent the gate lines 111 from being patterned when patterning the ITO film 139 to form the transparent conductive films 118 and the like, and it is possible to prevent the gate lines 111 from disconnecting.

Further, the transparent conductive films 118 are formed so as to reach the upper surface of the interlayer insulating film 140. Because of this, even when the transparent conductive films 118 are shifted to an outer edge side of the transparent substrate 131 from a prescribed location, it is possible to maintain a connected state between the transparent conductive films 118 and the gate lines 111. As a result, the yield of the manufactured liquid crystal display devices can be improved. Here, the ITO film 139 is patterned to form the transparent conductive films 118. However, an IZO film may be formed, and this IZO film may be patterned to form the transparent conductive films 118 and the like. Alternatively, a transparent conductive film other than the ITO film and the IZO film may be used. Further, when the metal film 132a is formed of molybdenum nitride (MoN); the metal film 132b is formed of aluminum (Al); and the metal film 132c is formed of molybdenum (Mo), resistance to chemicals can be secured when patterning the gate insulating film 133 and the like.

### Embodiment 2

A liquid crystal display device according to Embodiment 2 of the present invention is described using FIGS. 22 to 27. Here, of the configurations shown in FIGS. 22 to 27, configurations that are the same as or corresponding to the configurations shown in FIGS. 1 to 21 above are given the same reference characters, and their description is omitted.

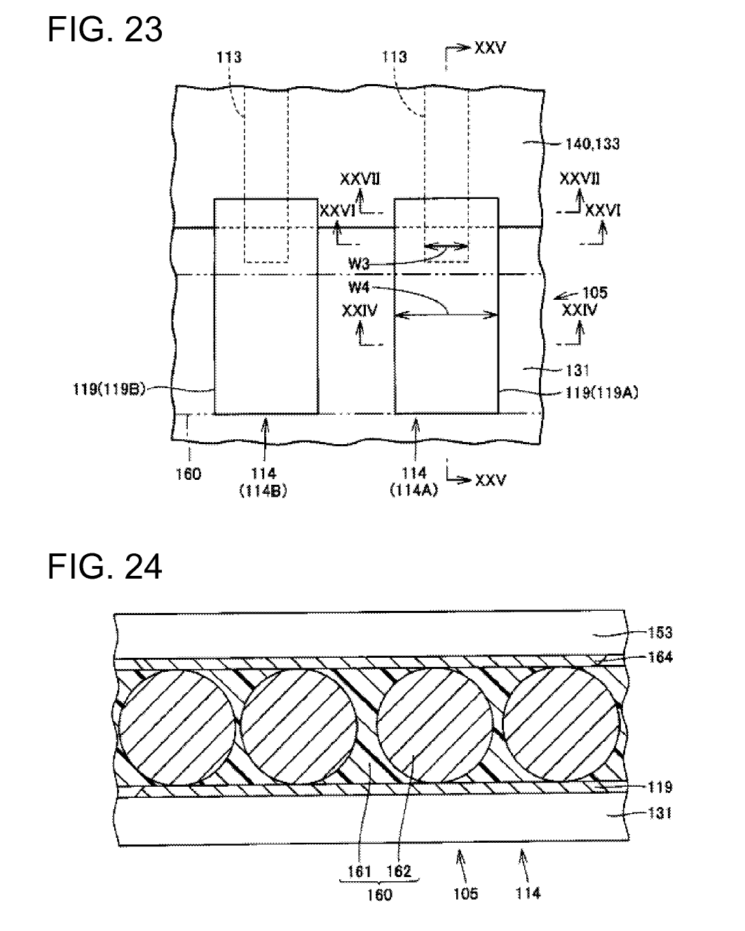

FIG. 22 is a cross-sectional view in the display region 103 of a liquid crystal display device of Embodiment 2. FIG. 23 is a plan view of source pads 114 formed in the peripheral region 105.

As shown in FIG. 23, ends of the data lines 113 reach a portion of the main surface of the transparent substrate 131 in which the peripheral region 105 is located. Of the data lines 113, the ends that reach the peripheral region 105 are exposed from the gate insulating film 133 and the interlayer insulating film 140. Transparent conductive films 119 are connected to portions of the data lines 113 that are exposed from the gate insulating film 133 and the interlayer insulating film 140. The transparent conductive films 119 are formed so as to cover the ends of the data lines 113.

The transparent conductive films 119 and the main surface of the transparent substrate 131 located in the peripheries of the transparent conductive films 119 are formed so as to be exposed from the interlayer insulating film 140 and the gate insulating film 133. Of the main surface of the transparent substrate 131, the main surface of the transparent substrate 131 that is located between a transparent conductive film 119A and a transparent conductive film 119B that is adjacent to the transparent conductive film 119A is exposed from the gate insulating film 133 and the interlayer insulating film 140.

The transparent conductive films 119 are formed so as to reach the ends of the data lines 113 from the main surface of the transparent substrate 131. At a portion where the transparent substrate 131 is located on the end of the data line 113, the width W4 of the transparent substrate 131 is formed wider than the width W3 of the data line 113.

Because of this, even if the positions of the transparent conductive films 119 are shifted slightly in a widthwise direction of the transparent conductive films 119 when forming the transparent conductive films 119, it is possible to secure connection between the data lines 113 and the transparent conductive films 119. This way, the yield of the liquid crystal display devices can be improved.

The transparent conductive films 119 are formed so as to reach the ends of the data lines 113 from the main surface of the transparent substrate 131. Portions of the transparent conductive films 119 that are located on the main surface of the transparent substrate 131 are planar, and function as terminals. The source pads 114 are formed by the transparent conductive films 119, which are formed this way.

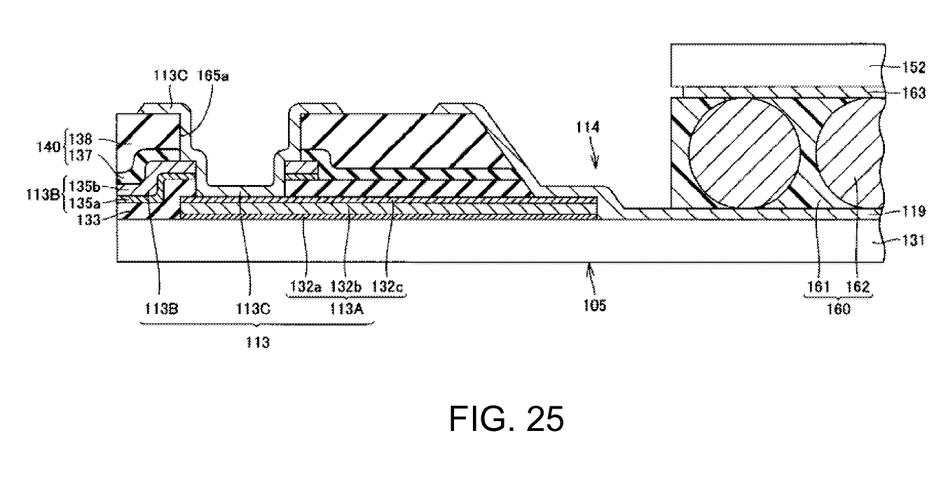

FIG. 24 is a cross-sectional view along the line XXIV-XXIV shown in FIG. 23. As shown in FIG. 24, on the upper surface of the transparent conductive film 119 that is located on the main surface of the transparent substrate 131, the anisotropic conductive film 160 is disposed. On the upper surface of the anisotropic conductive film 160, the source driver 153 is disposed. On the lower surface of the source driver 153, a connecting terminal 164 is formed.

The anisotropic conductive film 160 includes the insulating binder 161 and a plurality of conductive particles 162 disposed in the binder 161. Further, the transparent conductive film 119 and the connecting terminal 164 are electrically connected to each other by the conductive particles 162.

With respect to the source pad 114, the interlayer insulating film 140 and the gate insulating film 133 are not formed in the periphery of the source pad 114 either. Because of this, the connecting terminal 164 and the source pad 114 (transparent conductive film 119) can be brought closer to each other. Because the connecting terminal 164 and the transparent conductive film 119 can be brought closer to each other, the conductive particles 162 having small diameters can be used.

As a result, a plurality of conductive particles 162 can be aligned on the transparent conductive film 119. Furthermore, it is possible to prevent an occurrence of a short circuit between a source pad 114A and a source pad 114B, which are adjacent to each other.

FIG. 25 is a cross-sectional view along the line XXV-XXV shown in FIG. 23. As shown in FIG. 25, the data line 113 has a data line main body unit 113B, a transparent conductive film 113C, and a connection wiring line 113A.

The data line main body unit 113B is connected to the source electrode 135, and is led out from the source electrode 135 towards the peripheral region 105. The data line main body unit 113B includes the metal film 135a that is formed on the gate insulating film 133 and that is formed of titanium or the like and the metal film 135b that is formed on the metal film 135a and that is formed of aluminum.

The connection wiring line 113A is formed so as to extend from a side of an end of the data line main body unit 113B towards the peripheral region 105. The connection wiring line 113A is formed by the metal film 132a, the metal film 132b, and the metal film 132c, and is formed by the same metal films as the gate lines 111. The connection wiring line 113A is formed on the main surface of the transparent substrate 131. The connection wiring line 113A is formed at the same time as the gate lines 111 and the gate electrode 132 by laminating the metal film 132a, the metal film 132b, and the metal film 132c and then by patterning them. An end of the connection wiring line 113A is formed so as to reach the peripheral region 105 and to be exposed from the gate insulating film 133 and the interlayer insulating film 140.

The transparent conductive film 113C is formed on an inner circumferential surface of a contact hole 165a that is formed so as to run through the planarization film 138 and the passivation film 137. Inside the contact hole 165a, an end of the data line main body unit 113B is exposed. At a bottom portion of the contact hole 165a, an upper surface of the connection wiring line 113A is exposed.

Further, the transparent conductive film 113C is formed so as to reach an upper surface of the planarization film 138 through the upper surface of the connection wiring line 113A, the side faces and the upper surface of the end of the data line main body unit 113B, and the inner circumferential surface of the contact hole 165a. As a result, the connection wiring line 113A and the data line main body unit 113B are electrically connected to each other by the transparent conductive film 113C.

Here, when forming the contact hole 165a, the passivation film 137 and the planarization film 138 are formed first. Then, the planarization film 138 is patterned.

By patterning the planarization film 138, a portion of the planarization film 138 that is located in the peripheral region 105 is removed, and a portion of the contact hole 165a is formed.

Here, using the patterned planarization film 138 as a mask, the passivation film 137 is patterned to form the contact hole 165a. Further, the main surface of the transparent substrate 131 in the peripheral region 105 is exposed to the outside.

The end of the connection wiring line 113A on the peripheral region 105 side is exposed from the planarization film 138, the passivation film 137, and the gate insulating film 133. Further, the transparent conductive film 119 is formed so as to cover the end of the connection wiring line 113A and to reach the upper surface of the planarization film 138. Because of this, even if the position of the transparent conductive film 119 is shifted to the side of an outer periphery of the transparent substrate 131, it is possible to secure electrical connection between the transparent conductive film 119 and the connection wiring line 113A. As a result, the yield of the manufactured liquid crystal display devices can be improved.

Further, the transparent conductive film 119 is formed so as to cover a portion of the connection wiring line 113A that is exposed from the insulating films such as the planarization film 138 and the like. Because of this, when patterning the ITO film 139 to form the transparent conductive film 119, it is possible to prevent the connection wiring line 113A from being patterned.

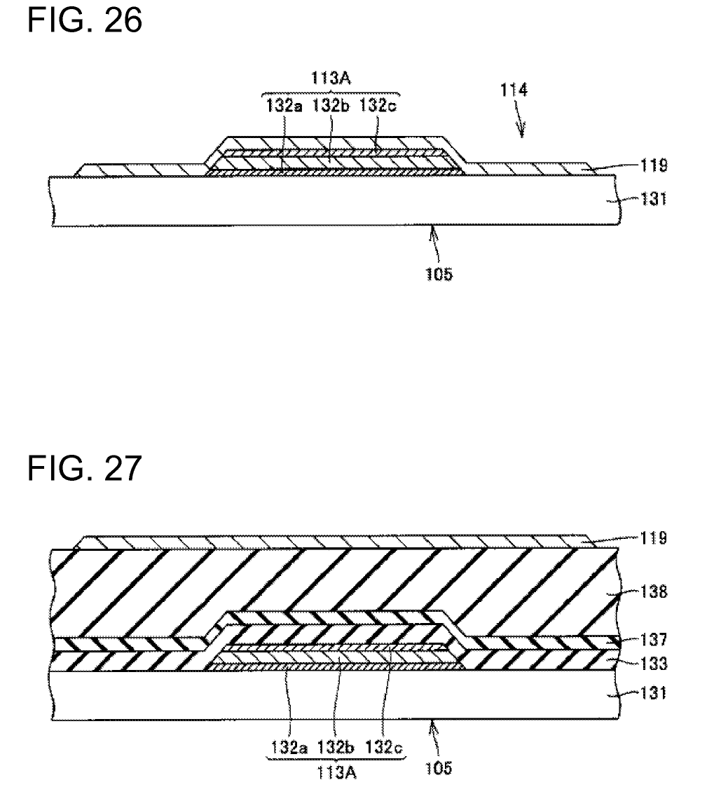

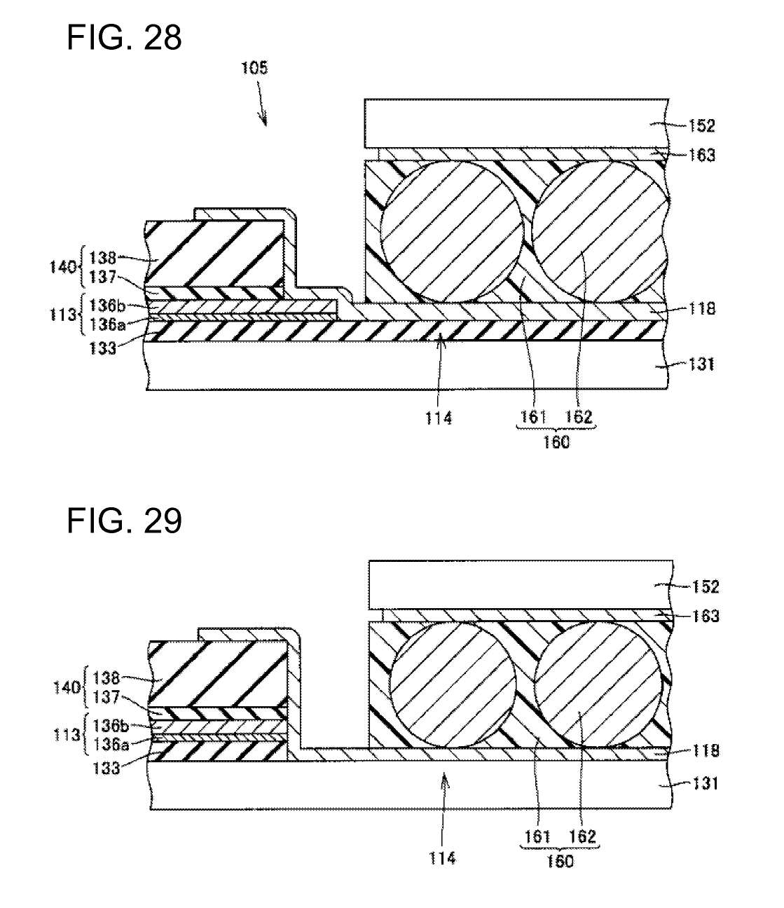

Here, FIGS. 26 and 27 are cross-sectional views along the line XXVI-XXVI and the line XXVII-XXVII in FIG. 24.

As shown in FIG. 26, the transparent conductive film 119 is formed from the main surface of the transparent substrate 131 that is adjacent to the connection wiring line 113A onto the upper surface and the side faces of the connection wiring line 113A. Further, on the side closer to the display region 103 than the peripheral region 105, the transparent conductive film 119 is formed on the upper surface of the planarization film 138.

### Embodiment 3

A liquid crystal display device according to Embodiment 3 is described using FIGS. 28 and 29. Here, of the configurations shown in FIGS. 28 and 29, configurations that are the same as or corresponding to the configurations shown in FIGS. 1 to 27 are given the same reference characters, and their description may be omitted.

FIG. 28 is a cross-sectional view of the peripheral region 105 of a liquid crystal display device of Embodiment 3 in which the source pad 114 is formed.

As shown in FIG. 28, the data line 113 is formed so as to reach the peripheral region 105. The end of the data line 113 located in the peripheral region 105 is formed so as to reach the peripheral region 105. The end of the data line 113 is formed so as to be exposed from the interlayer insulating film 140. Here, the interlayer insulating film 140 is formed so as to cover the display region 103 in which the thin film transistor 115 is formed.

The data line 113 is formed on the gate insulating film 133 formed on the main surface of the transparent substrate 131. In the liquid crystal display device of the present embodiment, the gate insulating film 133 is also formed in the peripheral region 105.

The transparent conductive film 118 is formed so as to reach the end of the data line 113 from the main surface of the transparent substrate 131 where the peripheral region 105 is located. Further, the transparent conductive film 118 is formed so as to reach the upper surface of the interlayer insulating film 140 from the upper surface of the data line 113.

The transparent conductive film 118 is formed on the upper surface of the gate insulating film 133, and is located above the main surface of the transparent substrate 131. On an upper surface of a portion of the transparent conductive film 118 that is located on the main surface of the transparent substrate 131 where the peripheral region 105 is located, the anisotropic conductive film (connecting member) 160 is disposed.

Of the transparent conductive film 118, a portion that is located on the gate insulating film 133 is formed in a planar shape. The connecting terminal 163 of the gate driver 152 is disposed above the portion formed in the planar shape. The anisotropic conductive film 160 is disposed on the upper surface of the transparent conductive film 118. The connecting terminal 163 and the transparent conductive film 118 are electrically connected to each other by the conductive particles 162 in the anisotropic conductive film 160.

Because of this, even when the position of the end of the data line 113 is shifted, it is sufficient if the end of the data line 113 and the transparent conductive film 118 are connected to each other, and the yield can be improved. Furthermore, the width of the transparent conductive film 118 is formed so as to be wider than the width of the end of the data line 113 in this source pad 114 as well in the same manner as Embodiment 1 and Embodiment 2 described above.

Here, the end of the data line 113 does not have to be exposed completely from the interlayer insulating film 140. In an example shown in FIG. 29, for example, an end face of the data line 113 is exposed from the interlayer insulating film 140, and the transparent conductive film 118 is formed so as to be in contact with the end surface of the data line 113.

### Embodiment 4

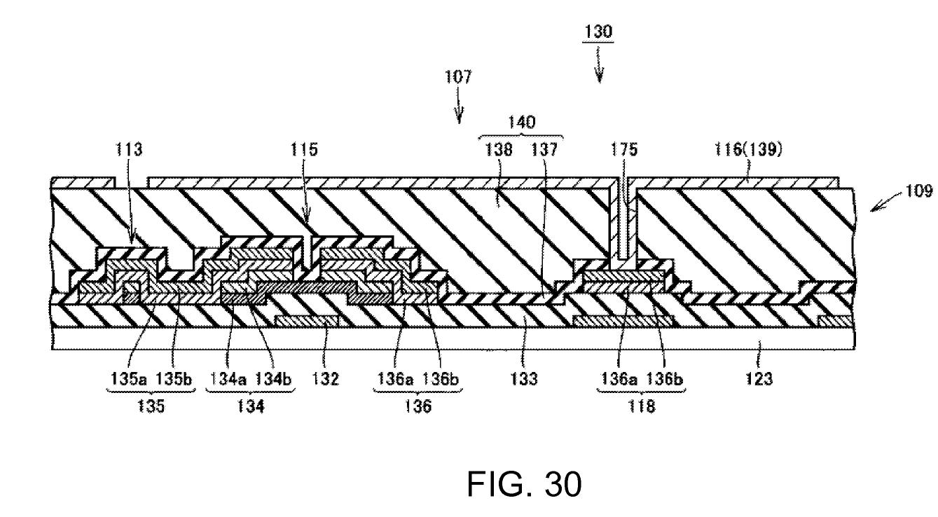

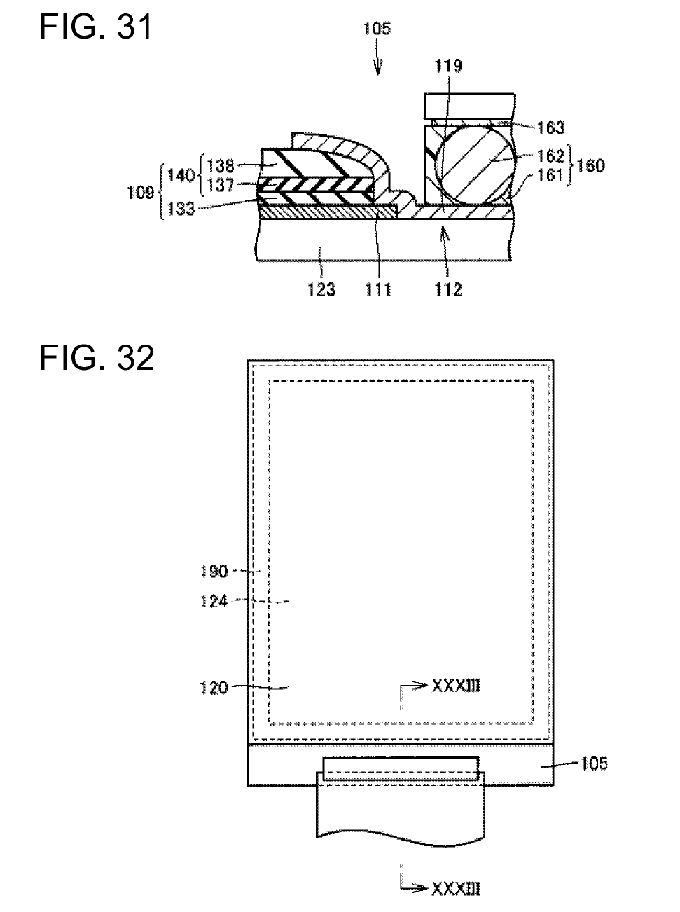

A liquid crystal display device according to Embodiment 4 is described using FIGS. 30 and 31. Here, of the configurations shown in FIGS. 30 and 31, configurations that are the same as or corresponding to the configurations shown in FIGS. 1 to 29 above are given the same reference characters, and their description may be omitted.

FIG. 30 is a cross-sectional view of the liquid crystal display device of Embodiment 4. FIG. 31 is a cross-sectional view of the gate pad 112.

In FIG. 30, the gate electrode 132 and the gate line 111 are constituted of an aluminum alloy material film.

This aluminum alloy material film has aluminum as a base material, an alloy component that includes at least one type of element selected from a group constituted of cobalt (Co), rhodium (Rh), nickel (Ni), palladium (Pd), carbon (C), silicon (Si), germanium (Ge), and tin (Sn), and another component that includes at least one type of element selected from a group constituted of copper (Cu), lanthanum (La), boron (B), neodymium (Nd), silver (Ag), gold (Au), platinum (Pt), and yttrium (Y).

By forming the gate line 111 and the gate electrode 132 using this aluminum alloy material film, the gate line 111 and the gate electrode 132 can be patterned by wet etching.

When patterning a multilayer metal film of titanium and aluminum to form the gate electrode 132, the gate line 111, and the like, for example, there is a risk of dust of titanium or the like generated inside a processing device. When the dust is generated, the dust may be attached onto a substrate, causing a risk of lowering the yield.

On the other hand, it is possible to prevent the dust from generating by wet etching the aluminum alloy material film described above in forming the gate line 111 and the gate electrode 132. Further, a difference in potential between the aluminum alloy material film described above and an ITO film is smaller than a difference in potential between an aluminum film and an ITO film. Because of this, even when the transparent conductive film 119 constituted of an ITO film or the like is brought into contact with the gate line 111, it is possible to prevent the gate line 111 from corroding.

Here, as shown in FIG. 31, the end of the gate line 111 is exposed from an insulating layer 109. Here, the insulating layer 109 includes the gate insulating film 133 and the interlayer insulating film 140 formed on the gate insulating film 133.

Here, a main surface of the transparent substrate 123 located in the peripheral region 105 is exposed from the insulating layer 109 in Embodiment 4 as well.

Further, the transparent conductive film 119 is formed so as to reach the end of the gate line 111 from a portion of the main surface of the transparent substrate 123 in which the peripheral region 105 is located.

Further, a portion of the transparent conductive film 119 that is formed directly on the main surface of the transparent substrate 123 is formed in a planar shape. Above this planar portion, the connecting terminal 163 is disposed.

Further, on an upper surface of the planar portion of the transparent conductive film 119, the anisotropic conductive film 160 is disposed. The transparent conductive film 119 and the connecting terminal 163 are electrically connected to each other.

In the liquid crystal display device of Embodiment 4, the metal films 135a and 136a of the source electrode 135 and the drain electrode 136 are formed of molybdenum. The metal films 135b and 136b are formed of the aluminum alloy material film described above.

By forming the source electrode 135 and the drain electrode 136 this way, the source electrode 135 and the drain electrode 136 can be formed by wet etching.

Further, by disposing the metal film constituted of molybdenum on a lower surface of the aluminum alloy material film, it is possible to prevent nickel or the like contained in the aluminum alloy material film from diffusing into the semiconductor layer.

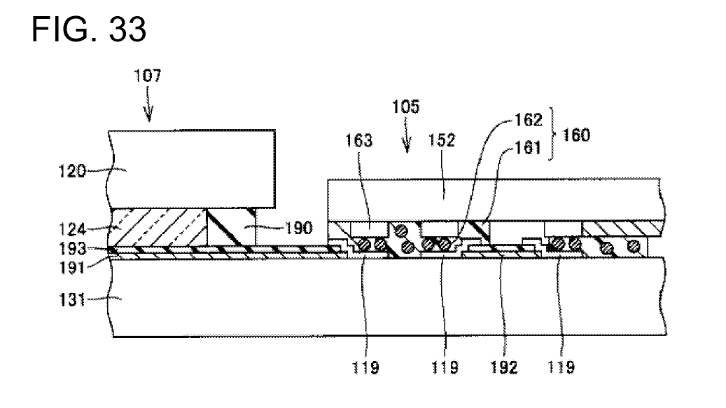

Here, FIGS. 32 and 33 show examples in which the present invention is applied in a COG (Chip On Glass).

FIG. 32 is a plan view of a liquid crystal display device in which the COG (Chip On Glass) is used. FIG. 33 is a cross-sectional view along the line XXXIII-XXXIII shown in FIG. 32.

As shown in FIG. 32, on a portion of the main surface of the transparent substrate 131 where the peripheral region 105 is located, a plurality of wiring lines 191 and wiring lines 192 are disposed. The wiring lines 191 are connected to the gate electrode, for example.

An end of the wiring line 191 is formed so as to be exposed from the insulating film 193 that is formed on an upper surface of the wiring line 191. The end of the wiring line 191 is located in the peripheral region 105, and the transparent conductive film 119 is connected to the end of the wiring line 191.

Here, the transparent conductive film 119 is formed so as to reach the end of the wiring line 191 from the main surface of the transparent substrate 131. Further, a portion of the transparent conductive film 119 that is formed directly on the main surface of the transparent substrate 131 is in a planar shape. The connecting terminal 163 of the gate driver 152 is disposed above the planar portion of the transparent conductive film 119.

The anisotropic conductive film 160 is disposed on the upper surface of the planar portion of the transparent conductive film 119, and the transparent conductive film 119 and the connecting terminal 163 are electrically connected to each other. Specifically, the connecting terminal 163 and the transparent conductive film 119 are connected to each other by the conductive particles 162 of the anisotropic conductive film 160.

Embodiments of the present invention were described above. However, the embodiments disclosed here should be considered as examples in every aspect, and should not be considered to be limiting. The scope of the present invention is shown by claims, and is not limited to 0 or a scope within the meaning and scope that are equivalent to the claims cover the subject matter within the appended claims as well as their equivalents.

### INDUSTRIAL APPLICABILITY

The present invention can be applied in a liquid crystal display device and in a method of manufacturing a liquid crystal display device. Particularly, the present invention is suitable for a liquid crystal display device that has an active matrix substrate and an opposite substrate and that has a terminal formed on the active matrix substrate and for a method of manufacturing such a liquid crystal display device.

### DESCRIPTION OF REFERENCE CHARACTERS

101 liquid crystal display panel
103 display region
104 non-display region
105 peripheral region
107 pixel arrangement region
111 gate lines
112 gate pads
113 data lines
113A connection wiring line
113B data line main body unit
113C transparent conductive film
114 source pads
115 thin film transistors
116 pixel electrodes
118 transparent conductive films
119 transparent conductive films
120 opposite substrate
121 color filter
122 opposite electrode
123 transparent substrate
124 liquid crystal layer
130 active matrix substrate
131 transparent substrate
132 gate electrode
133 gate insulating film
134 semiconductor layer
135 source electrode
136 drain electrode
137 passivation film
138 planarization film
140 interlayer insulating film
150 gate terminal
151 source terminal
152 gate drivers
153 source drivers
160 anisotropic conductive film
161 binder
162 conductive particles
163 connecting terminal
164 connecting terminal
300 liquid crystal display device

1. A liquid crystal display device, comprising:
a substrate having a main surface that includes a pixel arrangement region and a peripheral region formed in a periphery of said pixel arrangement region;
a switching element formed in said pixel arrangement region;
a wiring line that is connected to said switching element and that is formed such that an end thereof reaches said peripheral region;
a transparent conductive film formed on the main surface of said substrate located in said peripheral region and extending so as to reach the end of said wiring line located in said peripheral region;
a external terminal disposed above said transparent conductive films; and
a connecting member that is disposed between a portion of said transparent conductive films formed on the main surface of said substrate and said external terminal and that electrically connects said transparent conductive films to said external terminals.

2. The liquid crystal display device according to claim 1, further comprising:
an insulating film that is formed so as to cover a region of the main surface of said substrate in which said switching element is located,
wherein the end of said wiring line located in said peripheral region are formed so as to be exposed from said insulating film, and
wherein said transparent conductive film and the main surface of said substrate located adjacent to said transparent conductive films are exposed from said insulating film.

3. The liquid crystal display device according to claim 1, wherein a width of said transparent conductive film is greater than a width of said wiring lines.

4. The liquid crystal display device according to claim 1, wherein said transparent conductive film is formed so as to cover an upper surface and side faces of said wiring line.

5. The liquid crystal display device according to claim 2, wherein said transparent conductive film is formed so as to cover a portion of said wiring line that is exposed from said insulating film and so as to reach over said insulating film.

6. The liquid crystal display device according to claim 1, wherein the end of said wiring line is located on a side of said pixel arrangement region compared to a connected portion of said transparent conductive films and said connecting member.

7. A method of manufacturing a liquid crystal display device, the method comprising:
preparing a substrate having a main surface that includes a first region that becomes a pixel arrangement region and a second region that becomes a peripheral region located in a periphery of said pixel arrangement region;
forming a switching element in said first region;
forming a wiring line so as to be connected to said switching element and so as to reach said second region;
forming a transparent conductive film on the main surface of said substrate located in said second region so as to reach an end of said wiring line;
disposing a connecting member on an upper surface of a portion of said transparent conductive film located on the main surface of said substrate; and
disposing an external terminal on an upper surface of said connecting member to electrically connect said external terminal to said transparent conductive film.

8. The method of manufacturing a liquid crystal display device according to claim 7, wherein forming said switching element includes forming a gate electrode in said first region, forming a gate insulating film on said gate electrode, forming a semiconductor layer on said gate insulating film, and forming a source electrode and a drain electrode on said semiconductor layer,
wherein said wiring line is connected to either said gate electrode or said source electrode, and is formed such that an end thereof reaches said second region,
wherein the method further includes forming an insulating film on said source electrode and drain electrode and exposing the end of said wiring line from said insulating film, and
wherein said transparent conductive film is formed so as to be connected to said end of said wiring line exposed from said insulating film.

9. The method of manufacturing a liquid crystal display device according to claim 8, wherein a width of said transparent conductive film is formed to be wider than a width of said end of said wiring line.

10. The method of manufacturing a liquid crystal display device according to claim 8, wherein said transparent conductive film is formed so as to cover an upper surface and side faces of the end of said wiring line that is exposed from said insulating film.

11. The method of manufacturing a liquid crystal display device according to claim 8, wherein said transparent conductive film is formed so as to reach over said insulating film.
